(19) United States
(12) Patent Application Publication
(10) Pub. No.: US 2009/0039417 A1
(43) Pub. Date: Feb. 12, 2009

(54) Nonvolatile Flash Memory Device and Method for Producing Dielectric Oxide Nanodots on Silicon Dioxide

(75) Inventors: Jinghao Chen, Singapore (SG); Won Jong Yoo, Gyeonggi-do (KR); Siu Hung Daniel Chan, Singapore (SG)

Correspondence Address: DAVIDSON BERQUIST JACKSON & GOWDEY LLP, 4300 WILSON BLVD., 7TH FLOOR, ARLINGTON, VA, 22203, US

(73) Assignee: NATIONAL UNIVERSITY OF SINGAPORE, SINGAPORE (SG)

(21) Appl. No.: 11/884,459

(22) PCT Filed: Feb. 17, 2005
(86) PCT No.: PCT/SG2005/000046

§ 371 Date: Oct. 16, 2008

(51) Int. Cl. H01L 29/792; H01L 21/31

(52) U.S. Cl. 257/326; 438/787; 257/E21.679

(57) ABSTRACT

A method of producing dielectric oxide nanodots (104) embedded in silicon dioxide as well as a nonvolatile flash memory device comprising a trapping layer (224), the trapping layer (224) comprising dielectric oxide nanodots (104) embedded in silicon dioxide are presented. Firstly an ultra-thin metal film is deposited over a first dielectric layer including silicon dioxide provided on a substrate. Then, the ultra-thin metal film is annealed for forming metallic nanodots (104) on the first dielectric layer. Afterwards, the metallic nanodots (104) are annealed for forming dielectric oxide nanodots (104) on the first dielectric layer. Finally, the first dielectric layer and the dielectric oxide nanodots (104) are covered with a second dielectric layer of silicon dioxide for forming dielectric oxide nanodots (104) embedded in silicon dioxide.

### BACKGROUND

This invention relates generally to nonvolatile flash memory devices. In particular, this invention relates to a trapping layer having dielectric oxide nanodots embedded in silicon dioxide. Further, this invention relates to the fabrication of nonvolatile flash memory devices using dielectric oxide nanodots embedded in silicon dioxide as trapping layer.

Recently, the needs for high density nonvolatile flash memory devices at a low cost per bit have increased tremendously. Nonvolatile flash memory devices make use of field-effect transistors each having a trapping layer, also known as floating gate, between the gate and channel regions for storing electrical charge carriers representing the data bits to be stored.

Such nonvolatile flash memory devices have been aggressively scaled down in the past few decades. For the future, the “International Technology Roadmap of Semiconductors” (ITRS) 2003 shows that the scale down of nonvolatile flash memory devices will meet serious difficulty. In addition to the scaling down of the feature size, approaches including multi-level and multi-bit storage have received significant attention because they lead to substantial increase in storage density.

Good retention property is one of the most important requirements for nonvolatile multi-level and multi-bit memory devices. Discrete charge carrier storage resulting from nanocrystals (NCs) and Polysilicon-Oxide-Nitride-Oxide-Silicon (SONOS) type memory devices has been developed because the discreteness of charge carrier storage suppresses lateral migration of charge carriers, hence stored charge carriers are less vulnerable to oxide defects compared with conventional continuous floating gate memory devices.

Examples of nonvolatile memory devices of the NC- and SONOS-type are disclosed in U.S. Pat. Nos. 6,351,411 B2, 6,407,424 B2, 6,413,819 B1, 6,545,314 B2, and 6,724,038 B2, and in the PCT patent application WO 2004/048923 A2.

In NC-type memory devices, charge carriers are stored in NCs formed using Si, Ge, or metallic materials, which are embedded in various dielectric materials such as SiO₂, HfO₂ and HfAlO. However, charge carriers migrate laterally via direct tunneling (DT) and trap assisted tunneling (Frenkel-Poole (F-P) tunneling).

Therefore, the object of this invention is to provide a nonvolatile flash memory device and a method for fabricating the same, which overcome the above mentioned shortcomings and which has long retention and high reliability.

### SUMMARY OF THE INVENTION

The invention provides a novel method to assemble dielectric oxide nanodots on silicon(IV)dioxide (SiO₂) for a novel memory structure using the dielectric oxide nanodots embedded in SiO₂ for storage, which largely improves the data retention and reliability of flash memory devices. The novel method of this invention can be performed with conventional CMOS process techniques. Therefore, the problems presented in ITRS 2003 can be overcome.

In a first aspect, the invention provides a nonvolatile flash memory device comprising a trapping layer. The trapping layer comprises dielectric oxide nanodots being embedded in silicon(IV) dioxide (SiO₂). These dielectric oxide nanodots embedded in silicon(IV)dioxide (SiO₂) may be formed with the method according to the second aspect of this invention which is described below.

Therefore, the nonvolatile memory device of this invention employs trappy dielectric nanodots as charge carrier storage nodes, which are insulated by high-quality silicon(IV)dioxide (SiO₂).

Compared with the already known SONOS-type memory devices, lateral migration via trap assisted (F-P) tunneling can be significantly suppressed using this invention. And compared with the known NC-type memory devices, this invention can also provide additional advantage in electrical insulation between charge carriers within each charge storage node. Further advantages of this invention are the elimination of the deleterious diffusion and chemical instability of elemental NCs, such as Ni and Ge NCs.

Due to the fact that, compared with the prior art, the retention and reliability of nonvolatile memory devices can be improved further by this invention, the nonvolatile memory devices of this invention can be used in extreme environment, such as astrospace and radiation.

This invention even results in low cost per stored bit.

In a second aspect, the invention provides a method of producing dielectric oxide nanodots embedded in silicon(IV)dioxide (SiO₂).

This method includes the following steps: First, a substrate covered with a first dielectric layer of silicon(IV)dioxide (SiO₂) is provided. Secondly, a metal film (which can be an ultra-thin film) is deposited over the first dielectric layer. Then, the metal film is annealed in a first annealing step at a temperature below the melting point of the used metal, and in an inert gas ambient, preferably in an inert gas ambient which is substantially oxygen-free. Metallic nanodots are formed on the first dielectric layer by means of the first annealing step due to relaxation of layer stress, which, however, is limited by the surface mobility. The temperature used during this first annealing step provides the atoms of the metal used in the (ultra)-thin metal film with sufficient surface mobility such that the (ultra)-thin metal film self-assembles into a lower-total-energy state during a stress-relaxation process. To reduce the elastic energy carried by the stress built into this metal film during the deposition step, the (ultra)-thin metal film tends to break into individual islands, the metallic nanodots, along initial thickness perturbations acting as crystal nuclei. This first annealing step is carried out in an inert gas ambient that comprises as little as possible oxygen (O₂) such that the (ultra)-thin metal film changes into metallic nanodots, i.e. such that the ultra-thin metal film is not oxidized into a complete ultra-thin metal-oxide film during the first annealing step. The maximum amount of oxygen (O₂), which may be present during the first annealing step, the temperature used during and the duration of the first annealing step depend on the used metal and can be empirically determined based on the chosen experimental conditions. The empirical determination of the suitable reaction conditions (oxygen content, temperature, exposure of the metal film to the inert gaseous atmosphere) is well within the knowledge of the person skilled in the art. If aluminum (Al) is used as metal for the ultra-thin metal film, the concentration of oxygen (O₂) is typically less than 5 ppm and the temperature is typically chosen to be between about 500° C. to about 800° C.

Afterwards, the metallic nanodots are annealed in a second annealing step, preferably in an oxygenic ambient. Dielectric oxide nanodots are formed on the first dielectric layer by means of the second annealing step, which preferably is carried out in an oxygenic ambient. The concentration of oxygen (O₂) in this second annealing step is chosen such that the metallic nanodots completely change into dielectric oxide nanodots. It should be made sure that the duration of this second annealing step is sufficiently long for completely oxidizing the metallic nanodots, but not for a too extended period of time such that an oxidation of the substrate by oxygen (O₂) diffused through the first dielectric layer is prevented. Further, it should be noted that the duration of this second annealing step as well as the used concentration of oxygen (O₂) also depend on the used metal for the metallic nanodots, the dimension of the metallic nanodots, the temperature used during said second annealing step, etc. Likewise the first annealing step, suitable conditions for the second annealing step can be determined experimentally by a person of average skill in the art. If aluminum (Al) is used as metal for the ultra-thin metal film, the concentration of oxygen (O₂) is typically about 5,000 ppm and the temperature is typically chosen to be between about 500° C. to about 800° C. In the case of aluminum (Al), the resulting dielectric oxide nanodots typically have a maximum dimension of less than or equal to about 100 nm, preferably of about 5 nm. In addition, these aluminum oxide nanodots usually have a height of at least 1 nm, and are distributed two-dimensionally on the first dielectric layer with a density of about 5×10¹¹/cm².

Finally, the first dielectric layer and the dielectric oxide nanodots are covered with a second dielectric layer of silicon(IV) dioxide (SiO₂). Thus, the dielectric oxide nanodots are embedded in silicon(IV)dioxide (SiO₂). The first dielectric layer of the nonvolatile flash memory of the invention may have any suitable thickness and can be adjusted according to the desired application. In some embodiments this first dielectric layer comprises a thickness of a few nanometers, including, but by no means limited to, a thickness in the range of between about 2 nm and about 9 nm. In some of such embodiments the thickness of this first dielectric layer may be about 4.5 nm. Likewise, the second dielectric layer of the nonvolatile flash memory device of the invention may also have any suitable thickness, depending for example, also on the application. In some embodiments the second dielectric layer has a thickness that is thicker than the one of the first dielectric layer. In exemplary embodiments, the thickness of the second dielectric layer may be about 7 nm, in particular if the thickness of the first dielectric layer is less than about 7 nm.

It should be noted that the method as described above as second aspect of this invention can easily be incorporated in the common production of nonvolatile memory devices since this method is compatible to the CMOS process technology.

These and other features of the invention will be better understood in light of the following drawings and detailed description.

### BRIEF DESCRIPTION OF THE DRAWINGS

FIG. 1A to FIG. 1D illustrate four steps of the method according to an embodiment of this invention.

FIG. 2A to FIG. 2C show atomic force microscopy (AFM) images taken from sample surfaces after each step illustrated in FIG. 1A to FIG. 1C.

FIG. 3A to FIG. 3C show x-ray photoelectron spectra (XPS) taken from the sample surfaces after each step illustrated in FIG. 1A to FIG. 1C.

FIG. 4 shows a cross-sectional transmission electron microscopy (TEM) image of a nonvolatile flash memory device according to the embodiment of this invention.

FIG. 5A and FIG. 5B show perspective views of nonvolatile flash memory devices of the NC- and SONOS-type according to the prior art.

FIG. 5C shows a perspective view of the nonvolatile flash memory device according to one embodiment of the invention.

FIG. 6A and FIG. 6B illustrate the lateral migration of electrons with respect to the energy band structure of the storage capacitor inside the nonvolatile flash memory devices shown in FIG. 5A and FIG. 5B, respectively.

FIG. 6C illustrates the lateral migration of electrons with respect to the energy band structure of the storage capacitor inside the nonvolatile flash memory device shown in FIG. 5C.

FIG. 7A and FIG. 7B illustrate the vertical retention of electrons with respect to the quantum well structure of the storage capacitor inside the nonvolatile flash memory devices shown in FIG. 5A and FIG. 5B, respectively.

FIG. 7C illustrates the vertical retention of electrons with respect to the quantum well structure of the storage capacitor inside the nonvolatile flash memory device shown in FIG. 5C.

FIG. 8A shows a comparison diagram of the threshold voltage shifts of the nonvolatile flash memory devices shown in FIG. 5B and FIG. 5C with respect to retention time for different temperatures.

FIG. 8B shows a comparison diagram of the threshold voltages of the nonvolatile flash memory devices shown in FIG. 5B and FIG. 5C with respect to retention time for multi-level storage.

FIG. 9A shows a comparison diagram of the threshold voltage shifts of the nonvolatile flash memory device shown in FIG. 5C with respect to pulse width for different pulse voltages.

FIG. 9B shows a comparison diagram of the threshold voltage shifts of the nonvolatile flash memory device shown in FIG. 5B with respect to pulse width for different pulse voltages.

### DETAILED DESCRIPTION

In the following detailed description of the invention, reference is made to the accompanying drawings which form a part hereof, and in which are shown, by way of illustration only, specific embodiments of this invention. In the drawings, like numerals describe substantially similar components throughout the several views.

The term substrate used in the following description refers to any doped and/or undoped semiconductor structure having an exposed surface for the formation of an integrated circuit. Such a semiconductor structure may also comprise other layers that have been fabricated thereupon. Further, the terminals associated with the terms source and drain are actually determined by operating conditions of the nonvolatile flash memory device formed as a transistor, i.e. the terms source and drain are interchangeable. Additionally, the nonvolatile flash memory device described herein may be part of an arrayed memory, and may further comprise appropriate circuitry for driving and controlling the nonvolatile flash memory device, which circuitry as such is generally known in the art and therefore not described herein. The term nanodots as used in the present specification may nanocrystalline particles each having a maximum dimension less than or equal to 100 nm, less or equal to 50 nm or about 5 nm. In addition these particles may have a height of at least 1 nm. These nanocrystalline particles are separated from each other, i.e. do not have contact with each other. Moreover, the term oxide used in the present specification represents a material which was oxidized, preferably in an oxygenic ambient. Additionally, in the following the term silicon(IV)oxide (SiO₂) is abbreviated by the formulation silicon dioxide (SiO₂).

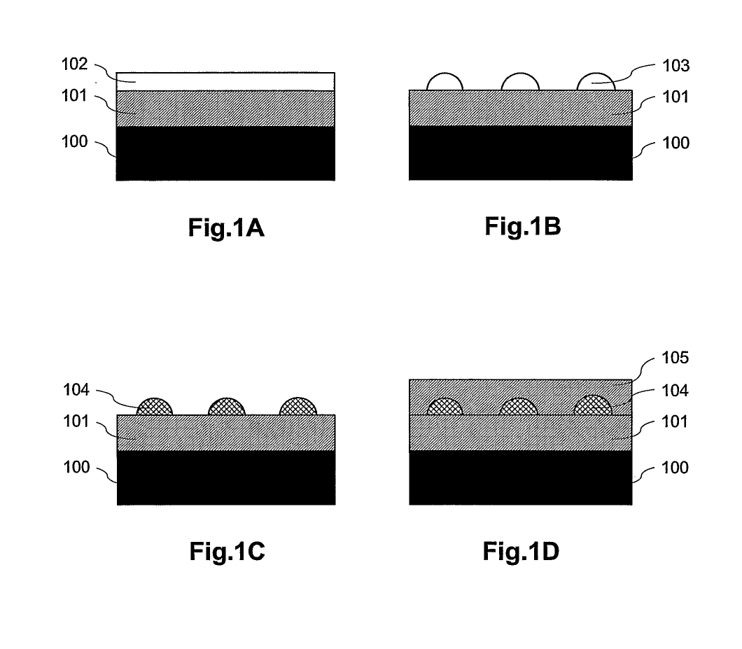

Referring now to FIG. 1A to FIG. 1C, the results of four steps of a method according to an embodiment of this invention (henceforth: the present method) are described in detail. FIG. 1A shows the result of a first step of the present method, i.e. after growing a first dielectric layer 101 comprising silicon dioxide (SiO₂) on a substrate 100 comprising silicon (Si), and after depositing an ultra-thin metal film 102 over the first dielectric layer 101. The substrate 100 consists of a p-type silicon wafer with its exposed surface being oriented according to the Miller indices (100). The first dielectric layer 101 has a thickness of about 4.5 nm and was grown in a pure oxygen ambient at a temperature of about 1,000° C. The ultra-thin metal film 102 has a thickness of about 2 nm, comprises aluminum (Al) and has been deposited by sputtering. Other deposition processes such as atomic layer deposition (ALD) can alternatively be used for depositing the ultra-thin metal film 102. It should be noted that the usage of silicon (Si) for the substrate 100 and of aluminum (Al) for the ultra-thin metal film 102, as well as the stated thicknesses and depositing/growth processes are just illustrative. For example, instead of aluminum (Al), one of the following materials can also be deposited as ultra-thin metal film 102: yttrium (Y), lanthanum (La), tantalum (Ta), titanium (Ti), hafnium (Hf), zirconium (Zr), tungsten (W), nickel (Ni), platinum (Pt), ruthenium (Ru), vanadium (V), molybdenum (Mo), and iridium (Ir).

FIG. 1B shows the result of a second step of the present method, i.e. after annealing the exposed ultra-thin metal film 102 in an inert gas ambient, i.e. a substantially oxygen-free ambient, at a temperature of 600° C. for 30 s. This substantially oxygen-free ambient mainly comprises nitrogen (N₂). The substantially oxygen-free ambient comprises as little as possible oxygen (O₂), preferably less than 5 ppm oxygen (O₂). Since this annealing in a substantially oxygen-free ambient takes place at a temperature below the melting point of the used metal for the ultra-thin metal film 102, the ultra-thin metal film 102 is not oxidized into a complete ultra-thin metal-oxide film but is transformed into metallic nanodots 103 due to relaxation of layer stress, which, however, is limited by the surface mobility. Hereinafter this annealing in a substantially oxygen-free ambient is also named nanodot formation annealing or ND formation annealing. The temperature used during this ND formation annealing gives the atoms of the metal used in the ultra-thin metal film 102 enough surface mobility such that the ultra-thin metal film 102 self-assembles into a lower-total-energy state during a stress-relaxation process. To reduce the elastic energy carried by the stress built into the ultra-thin metal film 102 during the deposition step, the ultra-thin metal film 102 tends to break into individual islands, the metallic nanodots 103, along initial thickness perturbations acting as crystal nuclei. In the present embodiment, the metallic nanodots 103 are aluminum-nanodots.

In a third step of the present method, these metallic nanodots 103 are then annealed in an oxygenic ambient also at a temperature of 600° C. for 30 s. Thus, the metallic nanodots 103 are oxidized into dielectric oxide nanodots 104. For this annealing in oxygenic ambient (the result thereof being shown in FIG. 1C), which hereinafter is also named oxidation annealing, the ambient contains nitrogen (N₂) and approximately 5,000 ppm oxygen (O₂). Therefore, in this embodiment, the aluminum-nanodots are oxidized into nanodots (NDs) containing aluminum(III) oxide (Al₂O₃). The concentration of oxygen (O₂) used in and the duration of the oxidation annealing are chosen such that the metallic nanodots 103 are completely oxidized into dielectric oxide nanodots 104, but such that substantially no oxygen (O₂) diffuses through the first dielectric layer 101 into the substrate 100. The resulting dielectric oxide nanodots 104 have a maximum dimension of less than or equal to 100 nm, which maximum dimension is due to the selected conditions during fabrication of the dielectric oxide nanodots 104. In this embodiment, the dielectric oxide nanodots 104 have a maximum dimension of about 5 nm due to the selected thickness of 2 nm for the ultra-thin metal film 102. Further, the dielectric oxide nanodots 104 are distributed two-dimensionally on the first dielectric layer 101 with a nanodot density of about 5×10¹¹/cm².

If yttrium (Y), lanthanum (La), tantalum (Ta), titanium (Ti), hafnium (Hf), zirconium (Zr), tungsten (W), nickel (Ni), platinum (Pt), ruthenium (Ru), vanadium (V), molybdenum (Mo), or iridium (Ir) is used instead of aluminum (Al) as material for the ultra-thin metal film 102, then the dielectric oxide nanodots 104 now mainly comprise yttrium(III)oxide (Y₂O₃), lanthanum(III)oxide (La₂O₃), tantalum(V) oxide (Ta₂O₅), titanium(IV) oxide (TiO₂), hafnium(IV)oxide (HfO₂), zirconium(IV)oxide (ZrO₂), tungsten(VI)oxide (WO₃), nickel(III) oxide (Ni₂O₃), platinum(IV)oxide peroxide (PtO₃), ruthenium(IV)oxide (RuO₂), vanadium(V) oxide (V₂O₅), molybdenum(V) oxide (Mo₂O₅), or iridium(III)oxide (Ir₂O₃), respectively. The amount of oxygen (O₂), which is used during the oxidation annealing of the ultra-thin metal film 102 that comprises one of the above mentioned metals or is formed from that metal depends on the used metal and can be empirically determined experimentally.

FIG. 1D shows the result of a fourth step of the present method, i.e. after finally covering the exposed first dielectric layer 101 and the dielectric oxide nanodots 104 with a second dielectric layer 105 comprising silicon dioxide (SiO₂). According to this embodiment, the second dielectric layer 105 has a thickness of about 7 nm and was disposed on the first dielectric layer 101 and the dielectric oxide nanodots 104 by means of a tetra-ethyl-ortho-silicate (TEOS) process at a temperature of about 675° C.

The first and second dielectric layers 101, 105 together with the dielectric oxide nanodots 104 form a trapping layer which is used for storing the charge carriers instead of a floating gate in a nonvolatile flash memory device. Therein, the first dielectric layer 101 acts for the dielectric oxide nanodots 104 as tunneling dielectric, and the second dielectric layer 105 acts for the dielectric oxide nanodots 104 as blocking dielectric. For completing the nonvolatile flash memory device (not shown in FIG. 1D), generally known processing steps are used. A detailed description of these generally known processing steps is omitted herein. Firstly, a gate layer is deposited on the second dielectric layer 105, secondly, at least the gate layer is patterned to form a gate electrode, thirdly, source and drain regions are formed in the substrate 100 on opposite sides with respect to the gate electrode, and, finally, an improvement annealing is performed. According to this invention, the gate layer is about 150 nm thick, comprises tantalum(III)nitride (TaN), and is deposited by reactive sputtering. Further, the source and drain regions are formed in the substrate 100 by an implantation of arsenic ions (As⁺) followed by an activation annealing at a temperature of about 1,000° C. for about 30 s. Furthermore, the improvement annealing is performed at a temperature of about 420° C. in a forming gas ambient for improving the quality of the interface between the substrate 100 and the first dielectric layer 101.

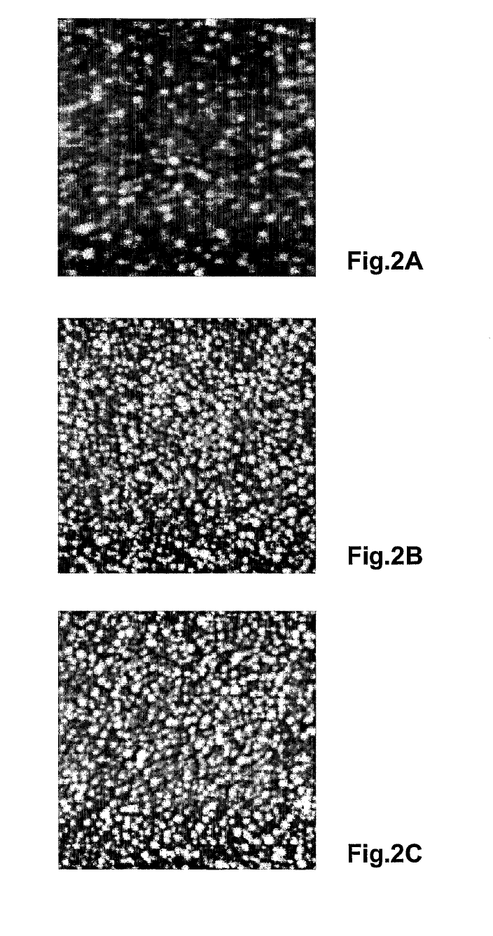

Referring now to FIG. 2A to FIG. 2C, atomic force microscopy (AFM) images taken from sample surfaces after each step illustrated in FIG. 1A to FIG. 1C are shown. These AFM images represent a topography analysis of the respective sample surfaces. The respective sample surface is in each case the surface of the ultra-thin metal layer 102 opposite the first dielectric layer 101, wherein in case of FIG. 2A the surface of the ultra-thin metal layer 102 is completely uncovered, wherein in case of FIG. 2B the surface of the ultra-thin metal layer 102 is partly covered by the metallic nanodots 103, and wherein in case of FIG. 2C the surface of the ultra-thin metal layer 102 is partly covered by the dielectric oxide nanodots 104. In particular, the AFM images confirm the formation of dielectric oxide nanodots 104 on the first dielectric layer 101.

As can be clearly taken from the AFM images shown in FIG. 2A to FIG. 2C, a nanodot-shaped topography can be observed only after the ND formation annealing and this topography remains almost unchanged during the oxidation annealing. This means that NDs were formed by the ND formation annealing, and the size and density were determined also by the ND formation annealing step. This is similar to the formation of inert metal nanocrystals (NCs) on silicon dioxide (SiO₂) in which stress relaxation of a deposited film by subsequent annealing results in rupture of the deposited film to end up as islands.

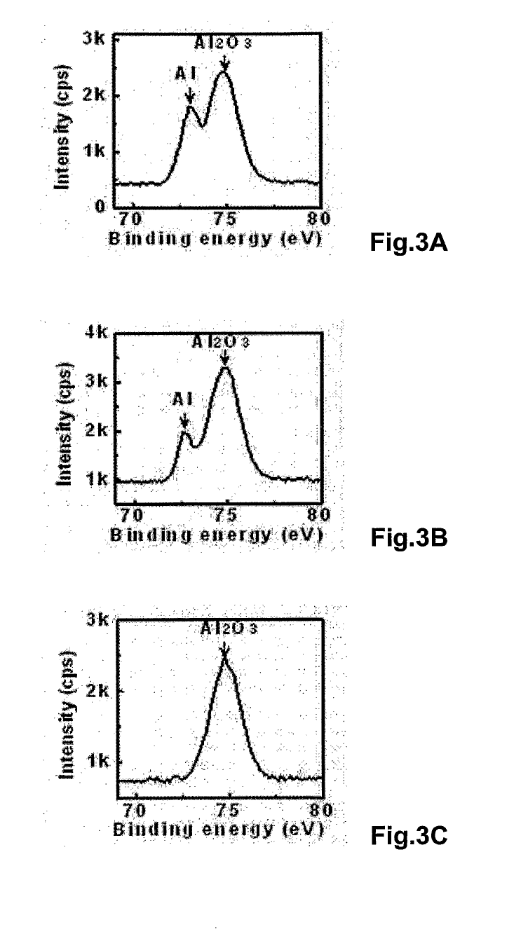

FIG. 3A to FIG. 3C show, in analogy to FIG. 2A to FIG. 2C, x-ray photoelectron spectra (XPS) taken from the sample surfaces after each step illustrated in FIG. 1A to FIG. 1C. The XPS of FIG. 3A to FIG. 3C are taken for the present embodiment of this invention, i.e. for a ultra-thin metallic film 101 comprising aluminum and for dielectric oxide nanodots 104 comprising aluminum(III)oxide (Al₂O₃). Therefore, the XPS of FIG. 3A shows that the initial ultra-thin metallic film 102 illustrated in FIG. 1A contains both aluminum (Al) and aluminum(III)oxide (Al₂O₃). This is because the surface of the ultra-thin metallic film 102 can be easily oxidized by oxygen (O₂) present in the atmosphere. Nevertheless, because of further aluminum (Al) underneath, the ultra-thin metallic film 102 still can conglomerate during the ND formation annealing. The XPS of FIG. 3B shows that the pure aluminum (Al) phase can still be detected after the ND formation annealing, hence another annealing step with oxygen (O₂) is performed. Finally, the XPS of FIG. 3C shows that aluminum (Al) NDs are now fully oxidized to aluminum(III)oxide (Al₂O₃) NDs at 600° C., indicating that 5,000 ppm oxygen (O₂) in nitrogen (N₂) is sufficient for the oxidation of NDs. However, due to the introduction of only a small amount of oxygen (O₂), no measurable increase in the thickness of the first dielectric layer 101 comprising silicon dioxide (SiO₂) can be observed.

It should be noted that the oxidation level of the ultra-thin metallic film 102, the initial thickness of the ultra-thin metallic film 102 and the temperature used during the ND formation annealing are adjustable conditions for controlling the size and density of the dielectric oxide nanodots 104. If the initial thickness of the ultra-thin metallic film 102 comprising aluminum (Al) is thin at about 1 nm, NDs cannot be formed by the subsequent ex-situ annealing, i.e. during the externally induced ND formation annealing. This is probably because the ultra-thin metallic film 102 has been fully oxidized after exposing to the atmosphere. On the other hand, a thicker initial ultra-thin metallic film 102 of about 6 nm results in larger NDs. Experimental results also prove that NDs comprising aluminum(III) oxide (Al₂O₃) cannot be formed by annealing ultra-thin films consisting of aluminum(III) oxide (Al₂O₃). This is likely because the surface mobility of aluminum(III)oxide (Al₂O₃) is lower than that of aluminum (Al), and thus self-agglomeration of aluminum(III)oxide (Al₂O₃) is less favorable compared to aluminum (Al). (It is noted that the melting temperature of aluminum (Al) is 660° C. and of aluminum(III)oxide (Al₂O₃) is 2,072° C., resulting in less fluidity of aluminum(III)oxide (Al₂O₃).) A systematic comparison yields that a 2 nm thick ultra-thin metallic film 102 comprising aluminum (Al) is likely to be near the optimum initial condition for assembling dielectric oxide nanodots 104 consisting of aluminum(III) oxide (Al₂O₃) with high areal density using the inventive two step annealing method. An annealing at 700° C. was also performed for 2 nm and 6 nm thick ultra-thin metallic films 102 comprising aluminum (Al). The results show that the higher temperature of the ND formation annealing tends to increase the size of the NDs, but to decrease the density of the NDs, especially for the ultra-thin metallic films 102 comprising aluminum (Al).

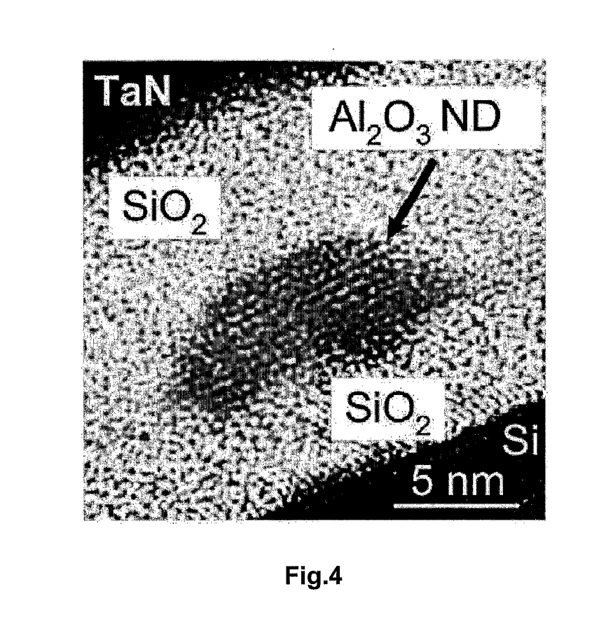

FIG. 4 shows a cross-sectional transmission electron microscopy (TEM) image of a nonvolatile flash memory device according to the embodiment of this invention. In particular, there is shown the substrate 101 (denoted with “Si” since comprising silicon in the present embodiment), the first and second dielectric layers 101, 105 (denoted “SiO₂” since comprising silicon dioxide in the present embodiment), the gate electrode (denoted with “TaN” since comprising tantalum(III)nitride in the present embodiment), and a single dielectric oxide nanodot 104 (denoted with “Al₂O₃ ND” since comprising aluminum(III)oxide in the present embodiment). As can be seen in FIG. 4, the dielectric oxide nanodot 104 (“Al₂O₃ ND”) has a maximum dimension of between 5 nm and 10 nm due to the controlled two step annealing method of this invention. Further, FIG. 4 shows that the method introduced in this invention is compatible with conventional CMOS process technology and does not have any side effect to other device structures, so that this invention can be easily applied by current semiconductor industry.

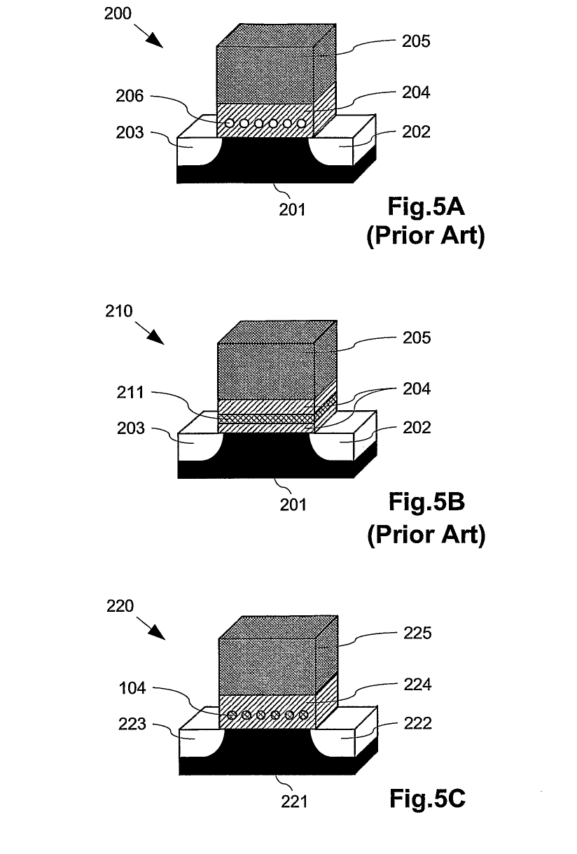

FIG. 5A and FIG. 5B show perspective views of nonvolatile flash memory devices of the NC- and SONOS-type according to the prior art, whereas FIG. 5C shows a perspective view of the nonvolatile flash memory device according to the embodiment of this invention.

In particular, FIG. 5A shows a perspective view of a nonvolatile flash memory device 200 of the NC-type according to the prior art, and FIG. 5B shows a perspective view of a nonvolatile flash memory device 210 of the SONOS-type according to the prior art. Both nonvolatile flash memory devices 200, 210 are formed as transistors having a storage capacitor between the gate electrode 205 and the channel region of the transistor. Therefore, the nonvolatile flash memory devices 200, 210 comprise a semiconductor substrate 201 whose cross-section parallel to the drawing plane of FIG. 5A and FIG. 5B has a shape which is comparable with an upside-down T-shape having a T-center section and T-side bars extending laterally from the bottom end region of the T-center section. The top end region of the T-center section forms the channel region of the transistor. The source and drain regions 202, 203 of the transistor are formed at opposite sides of the T-center section above the T-side bars. Above the T-center section there is located a gate dielectric layer 204, which separates the channel region and the source and drain regions 202, 203 from the gate electrode 205. The difference between the nonvolatile flash memory devices 200, 210 is that metallic or semiconductor nanocrystals (NCs) 206 are embedded in the gate dielectric layer 204 of the nonvolatile flash memory device 200 of the NC-type (see FIG. 5A), and that a dielectric continuous layer 211 is sandwiched inside the gate dielectric layer 204 of the nonvolatile flash memory device 210 of the SONOS-type (see FIG. 5B).

The nonvolatile flash memory device 220 according to the present embodiment of this invention may also be formed as a transistor having a storage capacitor between the gate electrode 225 and the channel region of the transistor. Therefore, the nonvolatile flash memory device 220 comprises a semiconductor substrate 221 whose cross-section parallel to the drawing plane of FIG. 5C has a shape which is comparable with an upside-down T-shape having a T-center section and T-side bars extending laterally from the bottom end region of the T-center section. The top end region of the T-center section forms the channel region of the transistor. The source and drain regions 222, 223 of the transistor are formed at opposite sides of the T-center section above the T-side bars. Above the T-center section there is located a trapping layer 224 forming the gate dielectric layer, which trapping layer 224 separates the channel region and the source and drain regions 222, 223 from the gate electrode 225. Inside the trapping layer 224 there are embedded dielectric oxide nanodots 104. The trapping layer 224 with the embedded dielectric oxide nanodots 104 has been fabricated by the present method as described with respect to FIG. 1A to FIG. 1D.

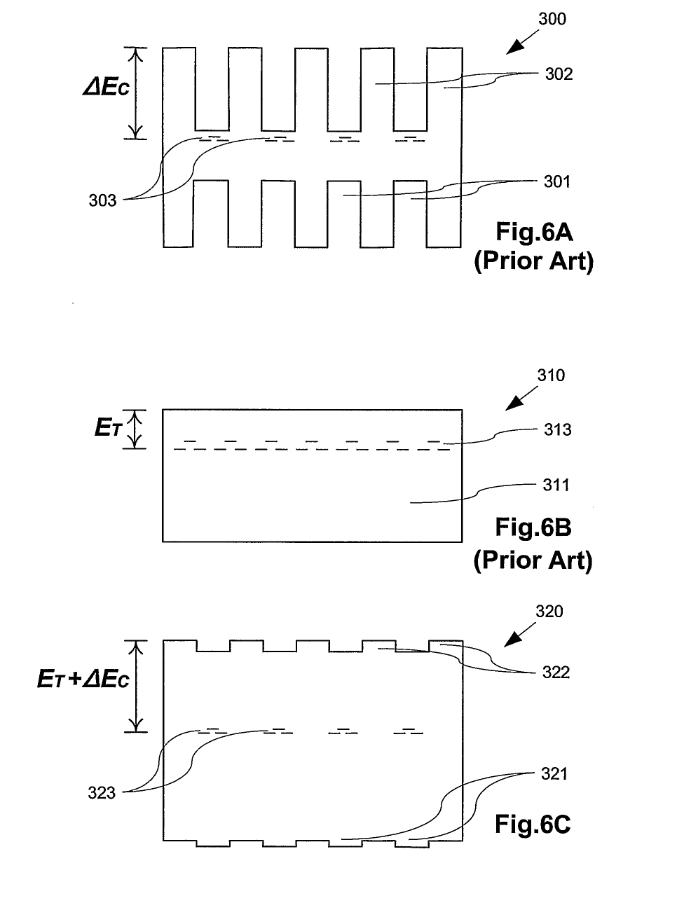

FIG. 6A to FIG. 6C illustrate the lateral migration of electrons with respect to the energy band structure of the storage capacitor inside the nonvolatile flash memory devices 200, 210, 220 shown in FIG. 5A to FIG. 5C, respectively.

In particular, FIG. 6A shows the lateral energy band structure 300 of the storage capacitor inside the nonvolatile flash memory device 200 shown in FIG. 5A. Therein, the nanocrystals (NCs) 206 are represented by NC energy bands 301 and the gate dielectric layer 204 electrically insulating electrons, which are stored in the NCs 206, in lateral direction is represented by inter-NC dielectric energy bands 302. Due to the metallic or semiconductor nature of the NCs 206, there exists a high conduction band offset ΔE_{C} between the NC energy bands 301 and the inter-NC dielectric energy bands 302. In the NCs 206 there are stored electrons represented by the energy level 303. Electrons can laterally migrate between adjacent NCs 206 by direct tunneling (DT).

The lateral energy band structure 310 of the storage capacitor inside the nonvolatile flash memory device 210 shown in FIG. 5B is shown in FIG. 6B. Therein, the gate dielectric layer 204 is represented by dielectric energy bands 311. The electrons stored in the dielectric continuous layer 211 are represented by the energy level 313. As can be gathered from the energy band structure 310, the electrons stored in the dielectric continuous layer 211 are electrically insulated in lateral direction. Due to the dielectric nature of the dielectric continuous layer 211, the electrons are confined by the trap level E_{T} inside the dielectric continuous layer 211. Electrons can laterally migrate in the dielectric continuous layer 211 by direct tunneling (DT) and trap assisted tunneling (Frenkel-Poole (F-P) tunneling).

As can be gathered from the lateral energy band structure 320 (see FIG. 6C) of the storage capacitor inside the nonvolatile flash memory device 220 shown in FIG. 5C, the advantages of the NC- and SONOS-type nonvolatile flash memory devices 200, 210 with respect to their lateral energy band structures 300, 310 are combined in the lateral energy band structure 320 of the inventive nonvolatile flash memory device 220 shown in FIG. 5C. Therein, the dielectric oxide nanodots (NDs) 104 are represented by ND energy bands 321 and the gate dielectric layer 224 electrically insulating electrons, which are stored in the NDs 104, in lateral direction is represented by inter-ND dielectric energy bands 322. Due to the dielectric nature of the NDs 104, there exists a conduction band offset E_{T}+ΔE_{C} between the ND energy bands 321 and the inter-ND dielectric energy bands 322 which is much higher than in the prior art. In the NDs 104 there are stored electrons represented by the energy level 323. Electrons can laterally migrate inside the NDs 104 by direct tunneling (DT) and trap assisted tunneling (Frenkel-Poole (F-P) tunneling), whereas electrons can laterally migrate between adjacent NDs 104 only by direct tunneling (DT).

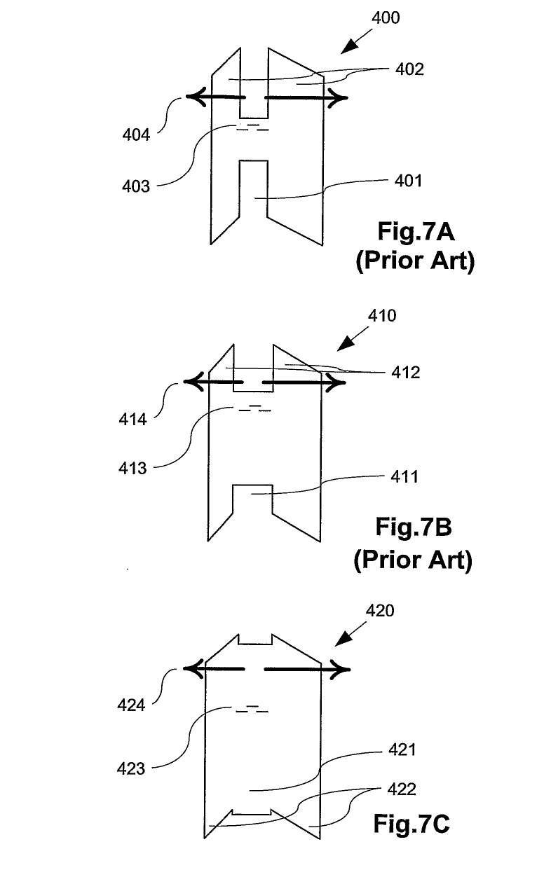

FIG. 7A to FIG. 7C illustrate the vertical retention of electrons with respect to the quantum well structure of the storage capacitor inside the nonvolatile flash memory devices 200, 210, 220 shown in FIG. 5A to FIG. 5C, respectively.

In particular, FIG. 7A shows the vertical quantum well structure 400 of the storage capacitor inside the nonvolatile flash memory device 200 shown in FIG. 5A for vertical retention of electrons stored in the nanocrystals (NCs) 206. Therein, the NCs 206 are represented by the NC quantum well base 401 and the gate dielectric layer 204 electrically retaining the electrons, which are stored in the NCs 206, in vertical direction is represented by confinement quantum well barriers 402. In the NCs 206 there are stored electrons 403. Electrons 403 can vertically escape 404 from the NC quantum well base 401 only by direct tunneling (DT).

The vertical quantum well structure 410 of the storage capacitor inside the nonvolatile flash memory device 210 shown in FIG. 5B is shown in FIG. 7B for vertical retention of electrons stored in the dielectric continuous layer 211. The vertical quantum well structure 410 shown in FIG. 7B is similar to the vertical quantum well structure 400 shown in FIG. 7A. Here, the quantum well base 411 represents the dielectric continuous layer 211 and the gate dielectric layer 204 electrically retaining the electrons, which are stored in the dielectric continuous layer 211, in vertical direction is represented by confinement quantum well barriers 412. In the dielectric continuous layer 211 there are stored electrons 413. Since the dielectric continuous layer 211 has a greater vertical extension than the NCs 206, the quantum well base 411 has a greater width in vertical direction of the nonvolatile flash memory devices than the NC quantum well base 401. Electrons 413 can vertically escape 414 from the quantum well base 411 only by direct tunneling (DT).

As can be seen from the vertical quantum well structure 420 (see FIG. 7C) of the storage capacitor inside the nonvolatile flash memory device 220 shown in FIG. 5C, the electrons 423 are stored in the dielectric oxide nanodots (NDs) 104 which are represented by ND quantum well bases 421 and are electrically confined in vertical direction of the nonvolatile flash memory device 220 by the gate dielectric layer 224 represented by confinement quantum well barriers 422. Due to the dielectric nature of the NDs 104, there exists a much lower quantum well difference between the ND quantum well bases 421 and the confinement quantum well barriers 422 than in the prior art, resulting in a lower vertically escape 424 of electrons 423 from the ND quantum well bases 421 by direct tunneling (DT).

Compared with the prior art, the energy band and vertical quantum well structures 320, 420 have the highest ability to suppress lateral migration and vertical escape of electrons from the NDs forming a charge storage layer in lateral direction, resulting in longer retention time and better reliability with respect to the prior art.

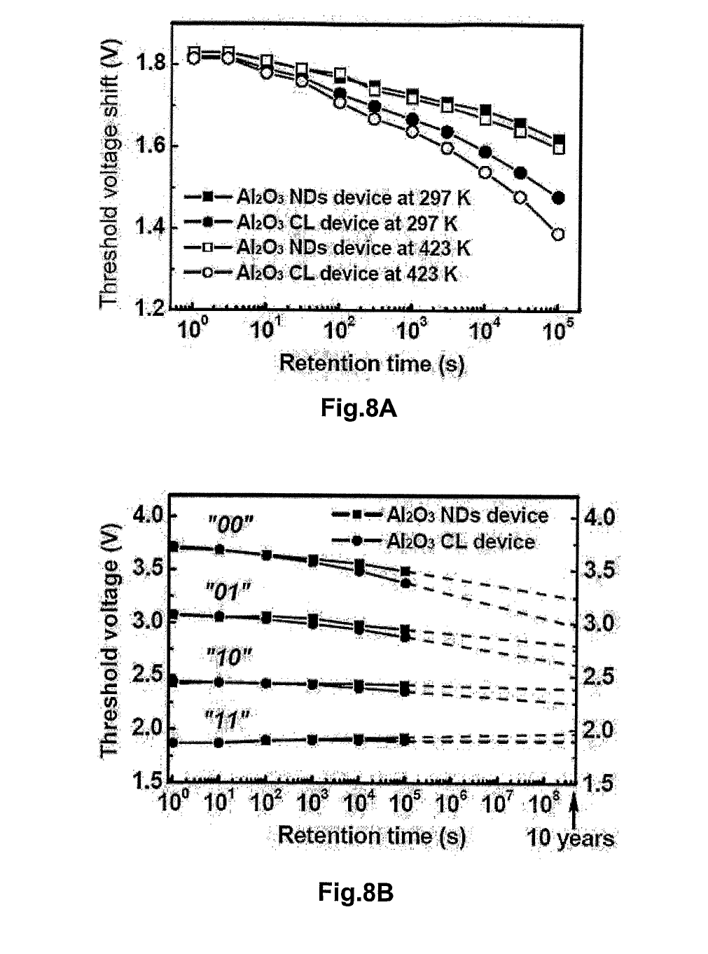

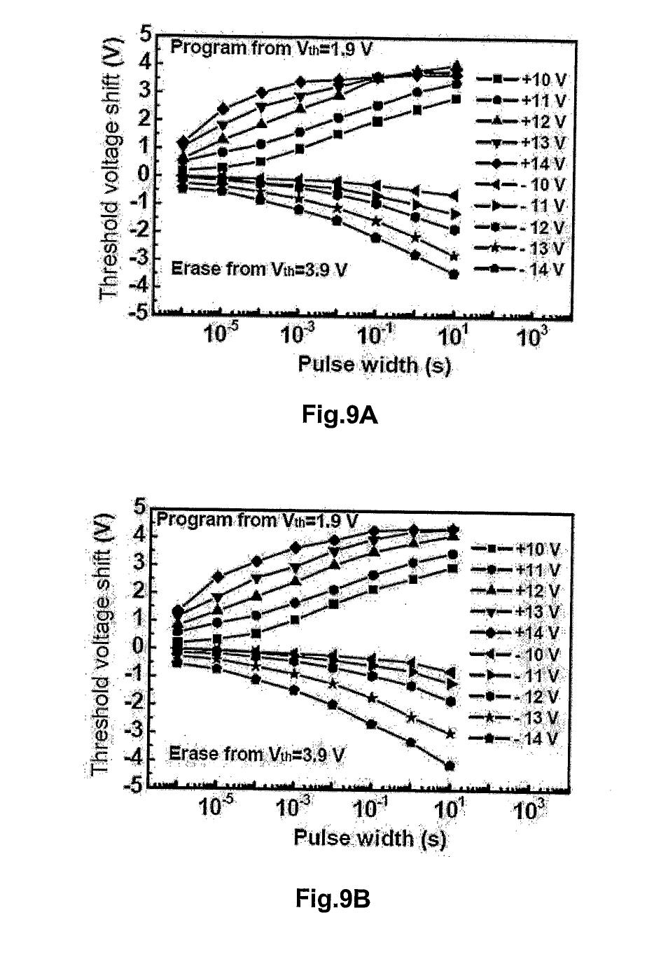

For the preparation of FIG. 8A, FIG. 8B, FIG. 9A and FIG. 9B, nonvolatile flash memory devices 210, 220 shown in FIG. 5B and FIG. 5C have been fabricated as test devices to investigate the electrical properties of the nonvolatile flash memory devices 210, 220. In order to compare this invention with the prior art, these test devices make use either of dielectric oxide nanodots (NDs) 104 comprising aluminum(III)oxide (Al₂O₃), hereinafter Al₂O₃ NDs device, or of a dielectric continuous trapping layer (CL) 211 comprising aluminum(III)oxide (Al₂O₃), hereinafter Al₂O₃ CL device. Except for the trapping layers (either NDs or CL), all the other details of the structure of the test devices were the same, as shown in FIG. 5B and FIG. 5C together with FIG. 4.

FIG. 8A shows a comparison diagram of the threshold voltage shifts of the nonvolatile flash memory devices shown in FIG. 5B and FIG. 5C with respect to retention time for different temperatures. In particular, the charge retention characteristics of the Al₂O₃ NDs device and of the Al₂O₃ CL device at 297K (24° C.) and 423K (150° C.) are compared. At 297K, the electron loss rate of the Al₂O₃ NDs device is much lower than that of the Al₂O₃ CL device over long periods. Since the materials and vertical structure of both test devices are the same, this difference must originate from the difference in the lateral dimension. As the conduction band edges of aluminum(III)oxide (Al₂O₃) and silicon dioxide (SiO₂) are at about the same level, the difference in their abilities in suppressing electron lateral migration via DT is insignificant when the tunneling lengths are the same; whereas the Al₂O₃ NDs device is much more effective to suppress electron lateral migration via F-P tunneling because silicon dioxide (SiO₂) contains much fewer traps than aluminum(III)oxide (Al₂O₃). Hence, it is very plausible that the reduced F-P tunneling probability results in the better retention of the Al₂O₃ NDs device. This is supported by the larger difference in charge retention properties of the two types of test devices at higher temperature, e.g. 423K.

FIG. 8B shows a comparison diagram of the threshold voltages (Vₜₕ) of the nonvolatile flash memory devices shown in FIG. 5B and FIG. 5C with respect to retention time for multi-level storage. The good retention properties demonstrated by the Al₂O₃ NDs device enable its potential application in multi-level storage. In FIG. 8B, multi-level storage operation of the Al₂O₃ NDs device and of the Al₂O₃ CL device at room temperature is demonstrated. The erased state near the fresh state is defined as state “11”, and pulses of 11 V for 10 ops, 12 V for 10 μs and 12 V for 100 μs are used to write the memory states of “10”, “01” and “00”, respectively. From the extrapolation of the retention property as shown in FIG. 8B, the Al₂O₃ NDs device can achieve 2-bits per cell multi-level storage with an expected retention time of 10 years if a proper sensing range is provided, because Vₜₕ of each state is maintained without overlapping with neighboring states. Meanwhile, in the Al₂O₃ CL device, it is shown that the highly programmed state (“00”) merges into the neighboring state (“01”) after 10 years, resulting in a memory error.

FIG. 9A and FIG. 9B show comparison diagrams of the threshold voltage shifts of the Al₂O₃ NDs device and of the Al₂O₃ CL device, respectively, with respect to pulse width for different pulse voltages. In particular, programming and erasing (P/E) efficiencies of the Al₂O₃ NDs device and of the Al₂O₃ CL device are shown. Assuming that the trap density in bulk aluminum(III)oxide (Al₂O₃) is the same for both test devices and that interface trap density is negligible, the theoretical programming speed of the Al₂O₃ NDs device should be lower than that of the Al₂O₃ CL device because of the lower trapping layer coverage, resulting in lower capture efficiency of the tunneling electrons. However, no significant degradation in programming efficiency of Al₂O₃ NDs device is observed in the fast programming (<100 μs) region. For example, both test devices can achieve a 1.85 V threshold voltage (Vₜₕ) shift by a 12 V, 100 μs pulse. A possible explanation is that the lost traps from reduced area coverage of aluminum(III)oxide (Al₂O₃) in the Al₂O₃ NCs device are compensated by the increased interface traps.

Although this invention has been described in terms of preferred embodiments, it will be understood that numerous variations and modifications may be made, without departing from the spirit and scope of this invention as set out in the following claims.

1. A nonvolatile flash memory device comprising a trapping layer, the trapping layer comprising dielectric oxide nanodots embedded in silicon dioxide.

2. The nonvolatile flash memory device as claimed in claim 1, wherein the dielectric oxide nanodots are embedded between a first dielectric layer and a second dielectric layer, the first and second dielectric layers comprising the silicon dioxide.

3. The nonvolatile flash memory device as claimed in claim 2, wherein the first dielectric layer comprises a thickness of between about 2 nm and about 9 nm.

4. The nonvolatile flash memory device as claimed in claim 3, wherein the first dielectric layer comprises a thickness of about 4.5 nm.

5. The nonvolatile flash memory device as claimed in claim 2, wherein the second dielectric layer comprises a thickness thicker than the first dielectric layer.

6. The nonvolatile flash memory device as claimed in claim 2, wherein the second dielectric layer comprises a thickness of about 7 nm.

7. The nonvolatile flash memory device as claimed in claim 1, wherein the trapping layer is arranged on a substrate.

8. The nonvolatile flash memory device as claimed in claim 7, wherein the substrate comprises silicon.

9. The nonvolatile flash memory device as claimed in claim 7, wherein a control gate layer is located above the trapping layer, and wherein source and drain regions are located on opposite sides of the trapping layer on and/or in the substrate.

10. The nonvolatile flash memory device as claimed in claim 1, wherein the dielectric oxide nanodots comprise a material selected from the group consisting of aluminum(III)oxide, yttrium(III)oxide, lanthanum(III)oxide, tantalum(V)oxide, titanium(IV)oxide, hafnium(IV)oxide, zirconium(IV)oxide, tungsten(VI)oxide, nickel(III)oxide, platinum(IV)oxide peroxide, ruthenium(IV)oxide, vanadium(V)oxide, molybdenum(V)oxide and iridium(III)oxide.

11. The nonvolatile flash memory device as claimed in claim 1, wherein the dielectric oxide nanodots comprise a maximum dimension of less than or equal to about 100 nm.

12. The nonvolatile flash memory device as claimed in claim 11, wherein the dielectric oxide nanodots comprise a maximum dimension of about 5 nm.

13. The nonvolatile flash memory device as claimed in claim 1, wherein the dielectric oxide nanodots are distributed two-dimensionally in the trapping layer with a density of about 5×10¹¹/cm².

14. A method of producing dielectric oxide nanodots embedded in silicon dioxide, comprising
a) providing a substrate covered with a first dielectric layer of silicon dioxide;
b) depositing an metal film over the first dielectric layer;
c) annealing the metal film at a temperature below the melting point of the used metal and in an inert gas ambient, thereby forming metallic nanodots on the first dielectric layer;
d) annealing the metallic nanodots in an oxygenic ambient, thereby forming dielectric oxide nanodots on the first dielectric layer; and
e) covering the first dielectric layer and the dielectric oxide nanodots with a second dielectric layer of silicon dioxide, thereby forming dielectric oxide nanodots embedded in silicon dioxide.

15. The method as claimed in claim 14, wherein step c) is carried out in a substantially oxygen-free ambient.

16. The method as claimed in claim 15, wherein step c) is carried out in an ambient comprising less than 5 ppm oxygen.

17. The method as claimed in claim 14, wherein step c) is carried out in an ambient substantially comprising nitrogen.

18. The method as claimed in claim 14, wherein step c) is carried out at a temperature between 500° C. and 800° C.

19. The method as claimed in claim 14, wherein step d) is carried out in an ambient comprising about 5,000 ppm oxygen.

20. The method as claimed in claim 14, wherein in step b) a metal is used that is chosen from the group consisting of aluminum, yttrium, lanthanum, tantalum, titanium, hafnium, zirconium, tungsten, nickel, platinum, ruthenium, vanadium, molybdenum and iridium.

21. The method as claimed in claim 14, wherein in step d) dielectric oxide nanodots are formed, the material of which is selected from the group consisting of aluminum(III)oxide, yttrium(III)oxide, lanthanum(III)oxide, tantalum(V)oxide, titanium(IV)oxide, hafnium(IV)oxide, zirconium(IV)oxide, tungsten(VI)oxide, nickel(III)oxide, platinum(IV)oxide peroxide, ruthenium(IV)oxide, vanadium(V)oxide, molybdenum(V)oxide and iridium(III)oxide.

22. The method as claimed in claim 14, wherein in step d) dielectric oxide nanodots are formed, whose maximum dimension is less than or equal to about 100 nm.

23. The method as claimed in claim 22, wherein in step d) dielectric oxide nanodots are formed, whose maximum dimension is about 5 nm.

24. The method as claimed in claim 14, wherein in step d) dielectric oxide nanodots are formed, which are distributed two-dimensionally on the first dielectric layer with a density of about 5×10¹¹/cm².

25. The method as claimed in claim 14, wherein the first dielectric layer in step a) is provided with a thickness of between about 2 nm and about 9 nm.

26. The method as claimed in claim 25, wherein the first dielectric layer in step a) is provided with a thickness of about 4.5 nm.

27. The method as claimed in claim 14, wherein the ultra-thin metal film in step b) is deposited with a thickness of about 2 nm.

28. The method as claimed in claim 14, wherein the second dielectric layer in step e) is deposited with a thickness thicker than the first dielectric layer.

29. The method as claimed in claim 14, wherein the second dielectric layer in step e) is deposited with a thickness of about 7 nm.

30. The method as claimed in Claim 14, wherein the first dielectric layer in step a) is provided on a substrate comprising silicon.
